(19) United States
(12) Patent Application Publication
(10) Pub. No.: US 2011/0068314 A1
(43) Pub. Date: Mar. 24, 2011

(54) SEMICONDUCTOR MEMORY DEVICE

(75) Inventors: Kensuke TAKAHASHI, Kanagawa-ken (JP); Takashi Shigeoka, Kanagawa-ken (JP)

(73) Assignee: KABUSHIKI KAISHA TOSHIBA, Tokyo (JP)

(21) Appl. No.: 12/790,320

(22) Filed: May 28, 2010

(30) Foreign Application Priority Data
Sep. 24, 2009 (JP) 2009-218718

(51) Int. Cl. H01L 45/00

(52) U.S. Cl. 257/4; 257/E45.001

(57) ABSTRACT

A semiconductor memory device of an embodiment includes: a cathode electrode formed of a p-type semiconductor material; a resistance change film being in contact with the cathode electrode; and an anode electrode being contact with the resistance change film.

This application is based upon and claims the benefit of priority from the prior Japanese Patent Application No. 2009-218718, filed on Sep. 24, 2009; the entire contents of which are incorporated herein by reference.

### BACKGROUND

1. Field

Embodiments described herein relate generally to a semiconductor memory device.

2. Background Art

The nonvolatile semiconductor memory, which is dominant on the market, is realized by the technique that, as represented by the flash memory and the SONOS memory, charges are stored in insulating films disposed above channels to vary the threshold voltage of the semiconductor transistors. It is essential to downsize the transistors to increase the capacity of the nonvolatile memory of such charge storing transistor-type nonvolatile memory. However, thinning the insulating film for retaining charges deteriorates the charge retaining performance due to increase of leak current. Thus, it is becoming difficult to increase the capacity of the charge storing transistor-type nonvolatile memory.

Then, a resistance change element having electric resistance value being able to be switched to values of two or more levels by some electric stimulus is noted as a nonvolatile memory element. This is because, in many cases, the resistance change element can detect electric resistance differences even downsized and will be advantageous for the downsizing when a principle and materials for varying the resistance value are available. In contrast to this, DRAM, for example, which is of the type of storing charges in the capacitance, has the signal voltage lowered as the charge storage decreases by the downsizing, which makes it difficult to detect signals.

As the technique of varying the electric resistance value, a plurality of techniques have been already proposed. For example, it is known that a voltage or a current is applied to the structure body of the metal/metal oxide/metal which sandwiches metal oxide by electrodes. Generally, the memory device using this property is called a resistance change memory. The phenomenon that a resistance value varies with voltage and current has been studied through the ages on various materials, and the studies have been reported. For example, a resistance change element using nickel oxide (NiO) is reported. This element can switch the resistance state between the OFF state of high resistance and the ON state of the low resistance by application of a prescribed voltage/current and even when the source power is turned off, can retain a resistance state at turning off.

Recently as well, a number of resistance random access memory devices using oxides of transition metals, such as Cu, Ti, Ni, Cu, Mo, etc., are proposed.

However, actually, in semiconductor memory devices manufactured by integrating a large number of such resistance change elements, some memory elements do not normally operate, and a problem of low reliability takes place.

### BRIEF DESCRIPTION OF THE DRAWINGS

FIG. 1 is a perspective view illustrating a semiconductor memory device according to a first embodiment of the invention;

FIG. 2 is a cross-sectional view of the semiconductor memory device according to the first embodiment;

FIGS. 3A to 7 are cross-sectional views in the processes illustrating the manufacturing method of the semiconductor memory device according to the first embodiment;

FIGS. 8A and 8B are graphs illustrating the operation of the semiconductor memory device;

FIG. 9 is a schematic view illustrating the energy band diagram during the forming operation and the set operation in a resistance change element having a cathode electrode formed of a metal;

FIGS. 10A and 10B are schematic views illustrating the energy band diagram of the resistance change element having the cathode electrode formed of a p-type semiconductor material;

FIG. 11 is a cross-sectional view illustrating a semiconductor memory device according to a second embodiment of the invention;

FIGS. 12 to 15 are cross-sectional views in the processes illustrating the manufacturing method of the semiconductor memory device according to the second embodiment; and

FIGS. 16A and 16B are schematic views illustrating the energy band diagram of a pillar in the second embodiment.

### DETAILED DESCRIPTION

According to embodiments of the invention, there is provided a semiconductor memory device including: a cathode electrode formed of a p-type semiconductor material; a resistance change film being in contact with the cathode electrode; and an anode electrode being contact with the resistance change film.

Embodiments of the invention will be described below with reference to the drawings.

First, a first embodiment of the invention will be described.

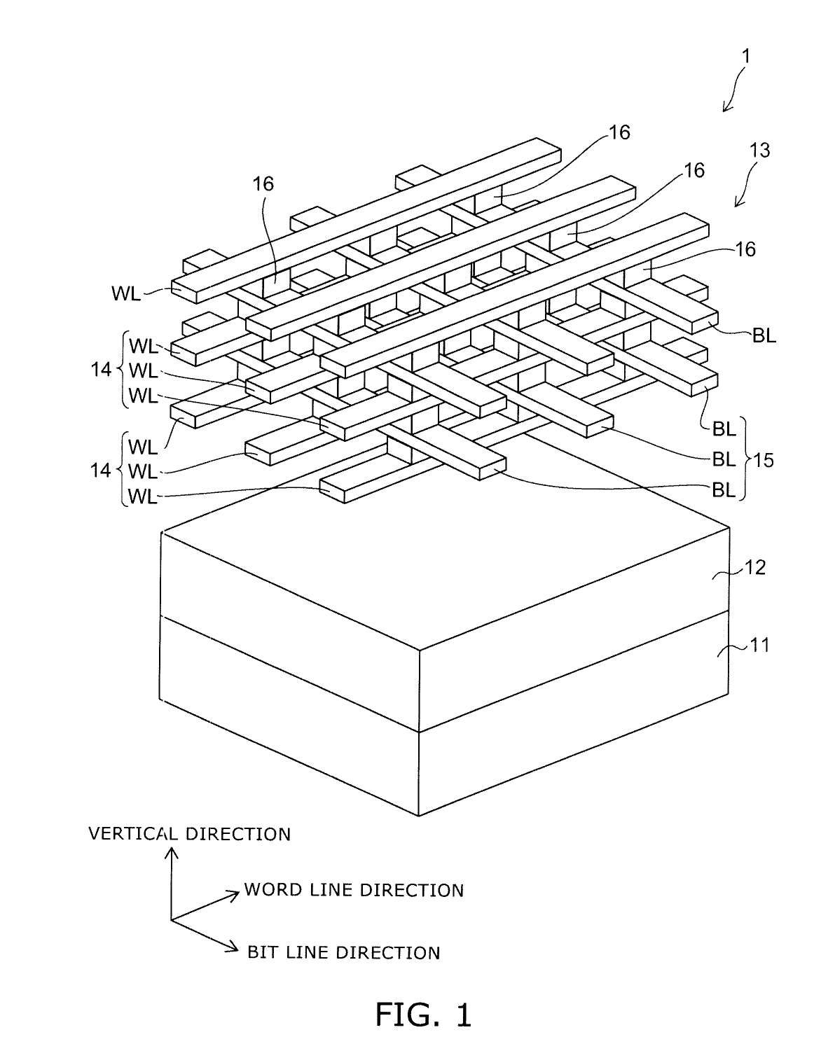

FIG. 1 is a perspective view exemplifying the semiconductor memory device according to this embodiment.

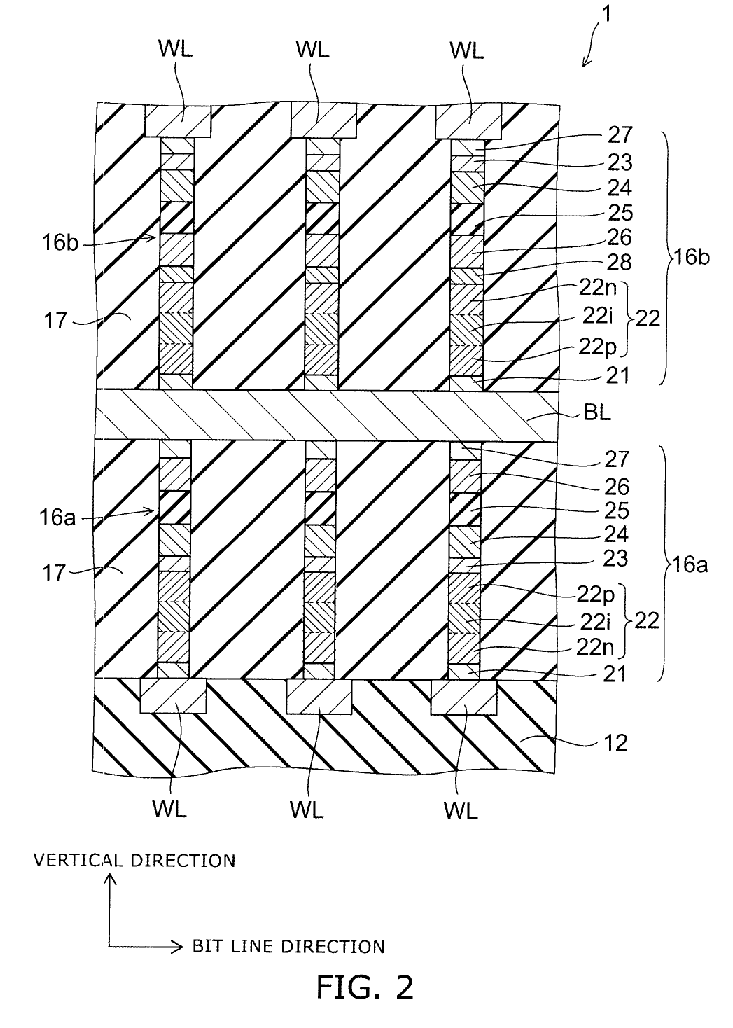

FIG. 2 is a cross-sectional view of the semiconductor memory device according to this embodiment.

The semiconductor memory device according to this embodiment is a ReRAM (Resistance Random Access Memory).

As illustrated in FIG. 1, in the semiconductor memory device 1 according to this embodiment, a silicon substrate 11 is provided. A drive circuit (not illustrated) is formed in an upper layer part of the silicon substrate 1 and on the upper surface of the silicon substrate 1. An inter-layer insulating film 12 of, e.g. silicon oxide is provided on the silicon substrate 11 to bury the drive circuit, and a memory cell unit 13 is provided on the inter-layer insulating film 12.

In the memory cell unit 13, word line interconnection layers 14 formed of a plurality of word lines WL extending in a direction (hereinafter called “word line direction”) parallel with the upper surface of the silicon substrate 11, and bit line interconnection layers 15 formed of a plurality of bit lines BL extending in a direction (hereinafter called “bit line direction”) intersecting the word line direction, e.g., orthogonal to the word line direction are alternately stacked with insulating layers formed therebetween. The word lines WL are not in contact with each other, the bit lines BL are not in contact with each other, and the word lines WL and the bit lines BL are not in contact with each other.

At the pericenters between the respective word lines WL and the respective bit lines BL, pillars 16 extending in a direction (hereinafter called “vertical direction”) to the upper surface of the silicon substrate 11 are provided. One pillar 16 forms one memory cell. That is, the semiconductor memory device 1 is a cross-point type device in which the memory cells are disposed at the respective pericenters between the word lines WL and the bit lines BL. Among the word lines WL, the bit lines BL and the pillars 16, inter-layer insulating films 17 are buried (see FIG. 2).

The configuration of the pillars 16 will be described.

As illustrated in FIG. 2, the pillars 16 include two kinds of pillars 16a having the word lines WL disposed below and the bit lines BL disposed above, and pillars 16b having the bit lines BL disposed below and the word lines WL disposed above.

In the pillars 16a, a barrier metal layer 21, a diode 22, a barrier metal layer 23, a cathode electrode 24, a resistance change film 25, an anode electrode 26 and a contact metal layer 27 are stacked from below (the side of the word lines) to above (the side of the bit lines) sequentially in the stated order. The barrier metal layer 21 is in contact with the word lines WL, and the contact metal layer 27 is in contact with the bit lines BL. The resistance change film 25 can have resistance values of two or more levels and can switch the resistance values by inputting prescribed electric signals. The resistance change film 25 is sandwiched between the cathode electrode 24 and the anode electrode 26 to form the resistance change elements. A higher potential is applied to the bit lines BL than to the word lines WL, and the cathode electrodes 24 are connected to the word lines WL via the diodes 22, etc, and the anode electrodes 26 are connected to the bit lines BL, whereby a relatively negative potential is applied to the cathode electrodes 24, and a relatively positive potential is applied to the anode electrodes 26. The diodes 22 form rectifying elements.

The sequence of the stacked layers of the resistance change elements in the pillars 16b is opposite to that in the pillars 16a. However, the pillars 16b are the same as the pillar 16a in that the rectifying elements are placed below the resistance change element, i.e., on the side of the silicon substrate 11. That is, in the pillars 16b, the barrier metal layer 21, diodes 22, a barrier metal layer 28, anode electrodes 26, the resistance change film 25, cathode electrodes 24, the barrier metal layer 23 and the contact metal layer 27 are arranged from below (the side of the bit lines) to above (the side of the word lines) sequentially in the stated order. The barrier metal layer 21 is in contact with the bit lines BL, and the contact metal layer 27 is in contact with the word lines WL. In the diodes 22, a p-type semiconductor layer 22p, an i-type semiconductor layer 22i and an n-type semiconductor layer 22n are disposed sequentially from below.

An characteristic of this embodiment is that the cathode electrodes 24 are formed of a p-type semiconductor material. The p-type semiconductor material is not limited to a specific material as long as the p-type semiconductor material is a p-type conductivity semiconductor, has good electric interface characteristics and good adhesion with respect to the resistance change film 26, and has resistance to the heat history of the manufacturing process. For example, p-type silicon may be used to ensure the controllability of the manufacturing process, the feasibility and the thermal resistance of the processing. As one example, the cathode electrodes 24 are formed of p-type silicon containing boron (B) as the acceptor. In this case, the concentration of the boron is, e.g., 1×10²⁰ cm⁻³.

The film thickness of the cathode electrodes 24 is not specifically limited as long as the characteristics of the p-type semiconductor is demonstrated and the film thickness is in a range in which the resistance value of the cathode electrodes 24 does not influence the operation of the memory cells. However, the film thickness of the cathode electrodes 24 is preferably 5 nm or more, more preferably 10 nm or more so as to ensure the uniformity of the film thickness and the acceptor concentration and suppress the influence on the characteristics of the resistance change elements by the interface layers with the resistance change film 25 and the interface with the barrier metal layer 23. The film thickness of the cathode electrodes 24 is preferably 20 nm or less, more preferably 15 nm or less to suppress the resistance of the cathode electrodes 24 low and make the processing of the pillars 16 easy.

The material forming the resistance change film 25 is preferably a material, e.g., including as the main component one kind of metal selected from the group consisting of nickel (Ni), titanium (Ti), zirconium (Zr), iron (Fe), vanadium (V), manganese (Mn), cobalt (Co) and hafnium (Hf), an alloy of two or more kinds of metals selected from the group, or an oxide or a nitride of them. The material may includes one or more kinds of elements selected from the group of silicon (Si), aluminum (Al), phosphorus (P) and arsenic (As) by about 1 to 30 percent by mass. For example, the resistance change film 25 is preferably formed of a metal oxide including hafnium oxide (HfO) as the main component.

The film thickness of the resistance change film 25 is preferably, e.g., 1 to 20 nm. Especially to facilitate the processing of the pillars 16, the film thickness of the resistance change film 25 is preferable below 10 nm including 10 nm. On the other hand, the film thickness of the resistance change film 25 is 2 nm or more to ensure the uniformity of the film and the reliability. The composition and film thickness of the resistance change film 25 can be combined so that the resistance value in the OFF state and the value of the forming voltage described later have the optimum values, respectively.

The material forming the anode electrodes 26 is not necessary to be a p-type semiconductor material. The material of the anode electrodes 26 is not specifically limited as long as the material has low resistivity, high thermal resistance and can ensure the interface characteristics and adhesiveness with respect to the resistance change film 25, but generally, a metal or a metal nitride is preferable so as to ensure the conductivity. For example, one kind of metal selected from the group consisting of nickel (Ni), titanium (Ti), zirconium (Zr), iron (Fe), vanadium (V), manganese (Mn), cobalt (Co) and hafnium (Hf), an alloy of two or more kinds of metals selected from the group, or an oxide or a nitride of them is preferable. For example, to realize good conductivity and process resistance, the material can be titanium nitride (TiN). The film thickness of the anode electrodes 26 is preferably, e.g., 5 to 15 nm.

The diodes 22 are diodes flowing a current only in the direction from the bit lines BL toward the word lines WL and specifically pin diodes. That is, in the diodes 22, the p-type semiconductor layer 22p, the i-type (intrinsic) semiconductor layer 22i and the n-type semiconductor layer 22n are stacked sequentially from the side of the bit lines BL. The diodes 22 are formed of, e.g., silicon (Si). The diodes 22 are connected to the cathode electrodes 24 via the barrier metal layer 23 in the pillars 16a. The diodes 22 are connected to the anode electrodes 26 via the barrier metal layer 28 in the pillars 16b.

In the cross-point type semiconductor memory device 1, a prescribed electric signal is applied to an arbitrary pillar 16 to control the resistance state of the resistance change film 25 included in the pillar 16 for writing, reading and deletion of data. For example, when a certain pillar 16 is selected, and a voltage of +5 V is applied to the pillar 16, a potential of, e.g., +5 V is applied to the bit line BL (the selection bit line) connected to the selected pillar 16, and a potential of, e.g., 0 V is applied to the other non-selected bit lines BL, a potential of 0 V is applied to the word line WL (the selection word line) connected to the selected pillar, and a potential of +5 V is applied to the other non-selected bit lines BL. However, in this case, a potential of −5 V is arbitrarily applied to the pillars 16 connected between the non-selected bit lines BL and the non-selected word lines WL. Then the diodes 22 are provided for the purpose of preventing the application of this −5 V voltage to the resistance change film 25 to prevent erroneous operations.

The material forming the barrier metal layer 23 must be a material having low resistivity and being able to prevent the diffusion of the material forming the cathode electrodes into the diodes 22. In addition to this, a material having a Fermi level (Ef) lower than the intrinsic Fermi level (Ei) of a p-type semiconductor material forming the cathode electrodes 24 is preferable. The barrier metal layer 23 is formed of preferably, e.g., one kind of metal selected from the group of ruthenium (Ru), titanium (Ti), tantalum (Ta), tungsten (W), hafnium (Hf) and aluminum (Al), an alloy of two or more kinds of metals selected from the group, or their oxide or nitride. For example, titanium nitride (TiN) is suitable in view of the above-described resistivity and the set operation and the process resistance of the memory cells described later. Preferably, the film thickness of the barrier metal layer 23 is, e.g., 5 to 15 nm.

The material forming the barrier metal layers 21, 28 may be a material having low resistivity, being able to prevent the diffusion of the material forming the diodes 22 and having high process resistance, and can be selected from, e.g., metals and metal nitrides. The material forming the contact metal layer 27 may be a material having low resistivity and having good junction with the materials forming the bit lines BL and the word lines WL and can be selected from metals or metal nitrides. Furthermore, the bit lines BL and the word lines WL are formed of a metal, e.g., tungsten (W).

Next, the method of manufacturing the semiconductor memory device according to this embodiment will be described.

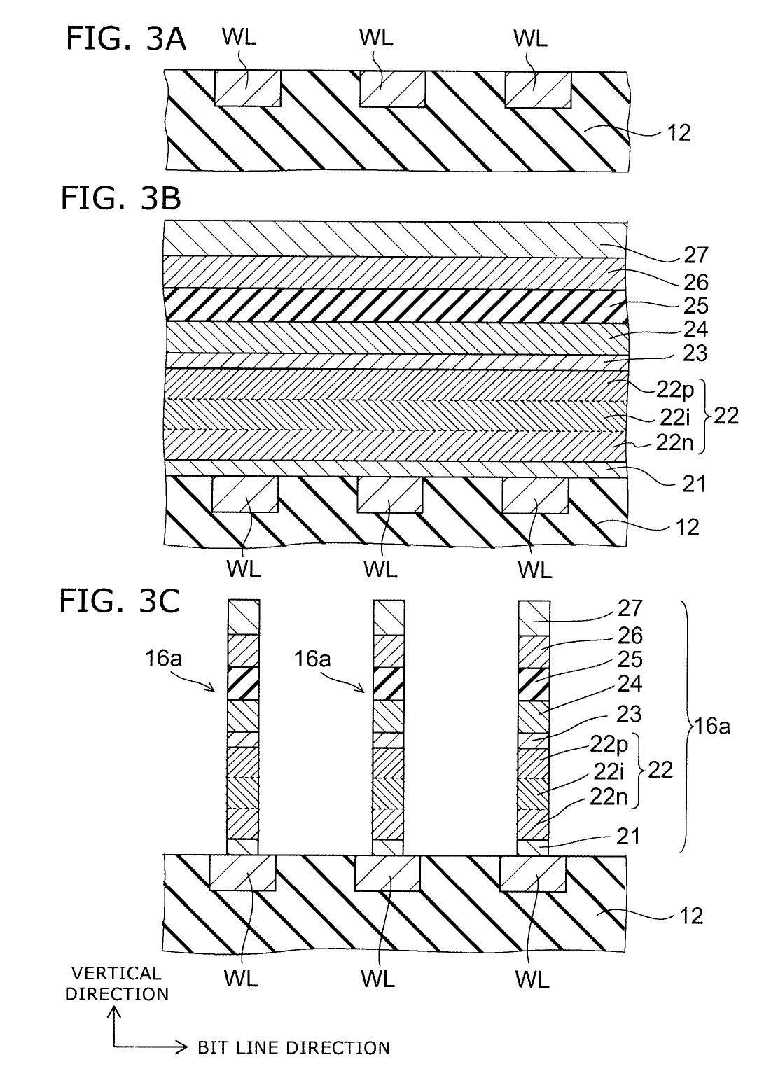

FIGS. 3 to 7 are cross-sectional views in the processes illustrating the manufacturing method of the semiconductor memory device according to this embodiment.

First, on the upper surface of the silicon substrate 11, MOSFETs (Metal-Oxide-Semiconductor Field-Effect Transistors) and contact, etc. are formed as illustrated in FIG. 1 to form the drive circuit. Then, the inter-layer insulating film 12 is formed on the silicon substrate 11 so as to bury the drive circuit.

Next, as illustrated in FIG. 3A, a plurality of word lines WL of a metal, such as tungsten (W) are formed in upper layer portions of the inter-layer insulating film 12 by RIE (Reactive Ion Etching) or damascening. The word lines WL are formed so as to extend in the word line direction, i.e., in the direction perpendicular to the drawing and are exposed on the upper surface of the inter-layer insulating film 12.

Next, as illustrated in FIG. 3B, the barrier metal layer 21, the diodes 22, the barrier metal layer 23, the cathode electrodes 24, the resistance change film 25, the anode electrodes 26 and the contact metal layer 27 are deposited sequentially in the stated order on the inter-layer insulating film 12. At this time, the n-type semiconductor layer 22n, the i-type semiconductor layer 22i and the p-type semiconductor layer 22p are deposited sequentially in the stated order to form the diodes 22. For example, silicon doped with a donor of phosphorus (P) or the like is deposited to form the n-type semiconductor layer 22n, non-doped silicon is deposited to form the i-type semiconductor layer 22i, and silicon doped with an acceptor of boron (B) or the like is deposited to form the p-type semiconductor layer 22p. The cathode electrodes 24 are formed of a p-type semiconductor material, e.g., silicon doped with boron.

Next, as illustrated in FIG. 3C, the stacked body including layers from the contact metal layer 27 to the barrier metal layer 21 is processed into pillars by RIE. Thus, a plurality of the pillars 16a are formed on the word lines WL.

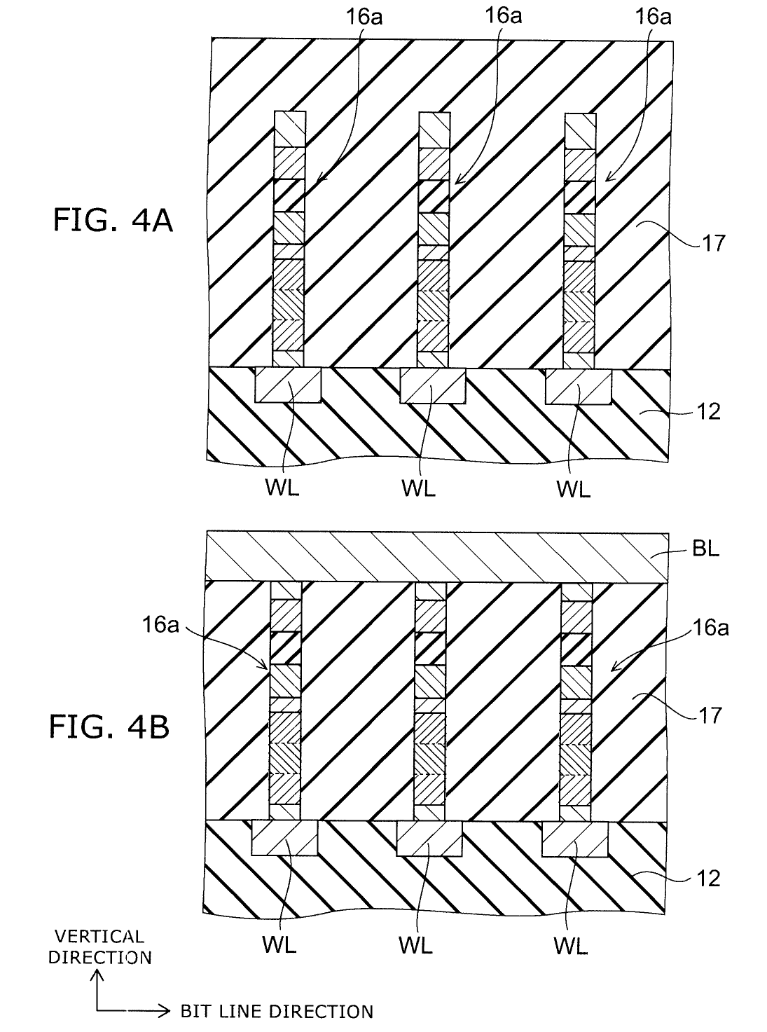

Next, as illustrated in FIG. 4A, the inter-layer insulating film 17 is deposited on the inter-layer insulating film 12 to bury the pillars 16a. Then, CMP (Chemical Mechanical Polishing) is made to planarize the upper surface of the inter-layer insulating film 17.

Next, as illustrated in FIG. 4B, a plurality of bit lines BL of a metal, such as tungsten (W) or the like are formed in upper layer portions of the inter-layer insulating film 17. The bit lines BL are formed so as to contact the upper surfaces of the pillars 16a and extend in the bit line direction. The bit lines BL are exposed on the upper surface of the inter-layer insulating film 17.

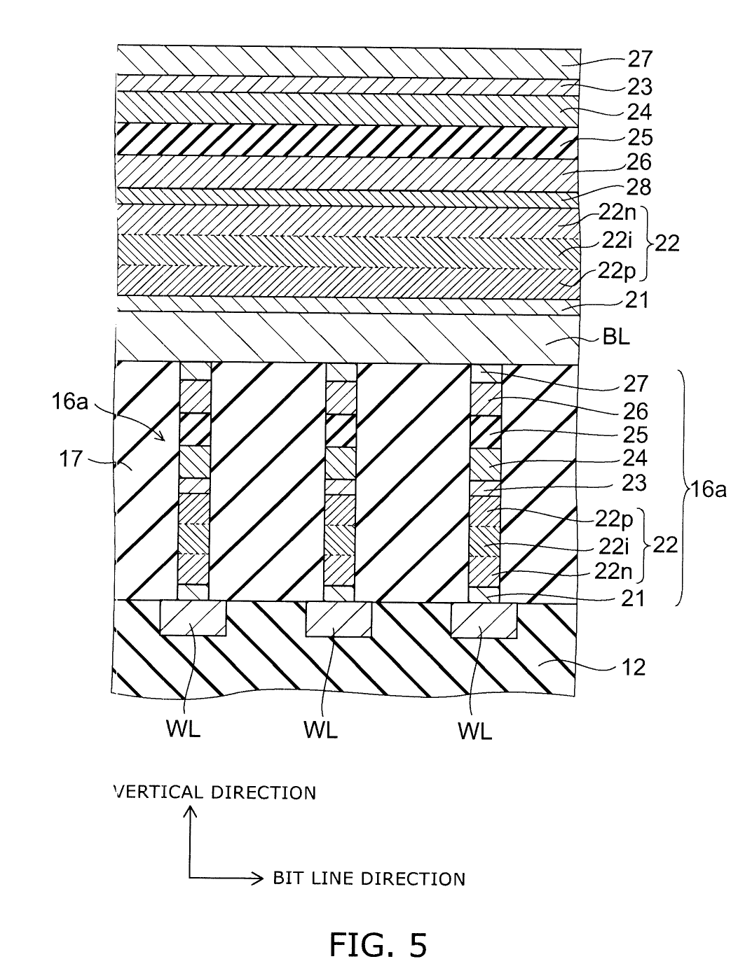

Next, as illustrated in FIG. 5, the barrier metal layer 21, the diodes 22, the barrier metal layer 28, the anode electrodes 26, the resistance change film 25, the cathode electrodes 24, the barrier meal layer 23 and the contact metal layer 27 are sequentially deposited in the stated order on the inter-layer insulating film 17. That is, the stacking order of the cathode electrodes 24, the resistance change film 25 and the anode electrodes 26 is opposite in comparison with the process illustrated in FIG. 3B. The direction of the diodes 22 is made opposite, and the p-type semiconductor layer 22p, the i-type semiconductor layer 22i and the n-type semiconductor layer 22n are deposited sequentially in the stated order to form the diodes 22.

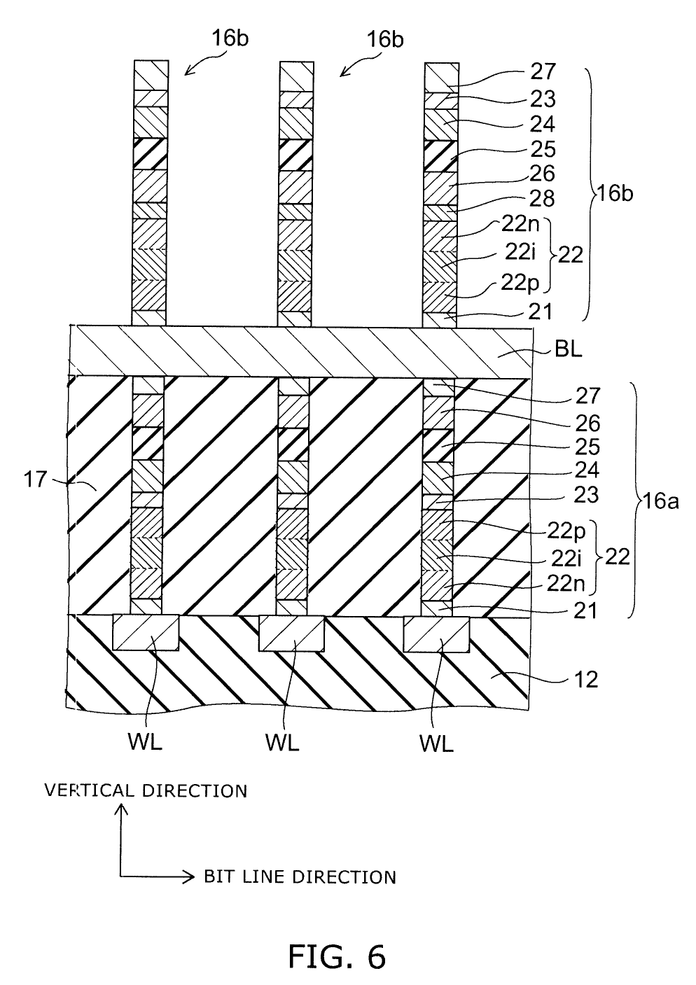

Next, as illustrated in FIG. 6, the stacked body formed on the inter-layer insulating film 17 is processed into pillars by RIE. Thus, a plurality of the pillars 16b are formed on the bit lines BL.

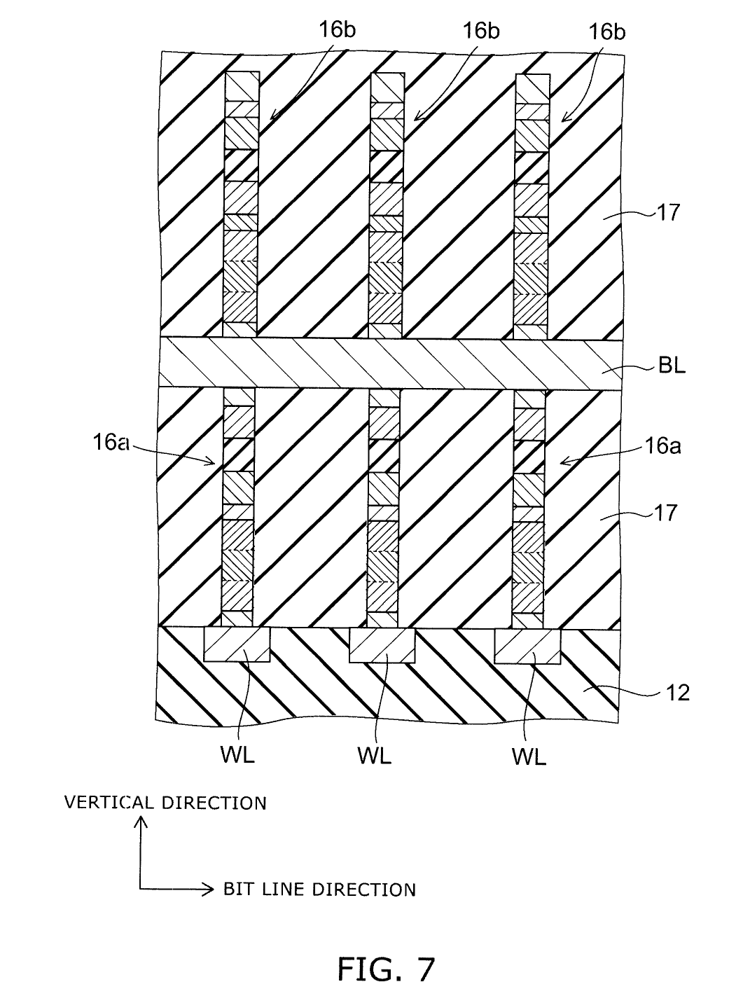

Then, as illustrated in FIG. 7, the inter-layer insulating film 17 is further deposited to bury the pillars 16b. Then, the upper surface of the inter-layer insulating film 17 is planarized by CMP.

Next, word lines WL are formed in upper surface portions of the inter-layer insulating film 17, which is the second layer, as illustrated in FIG. 2. The above-described process is repeated to form the word lines WL, the pillars 16a, the bit lines BL and the pillars 16b repeatedly, and the memory cell unit 13 including the stacked cross-point cell array is formed. Thus, the semiconductor memory device 1 is manufactured.

Next, the operation of this embodiment will be described.

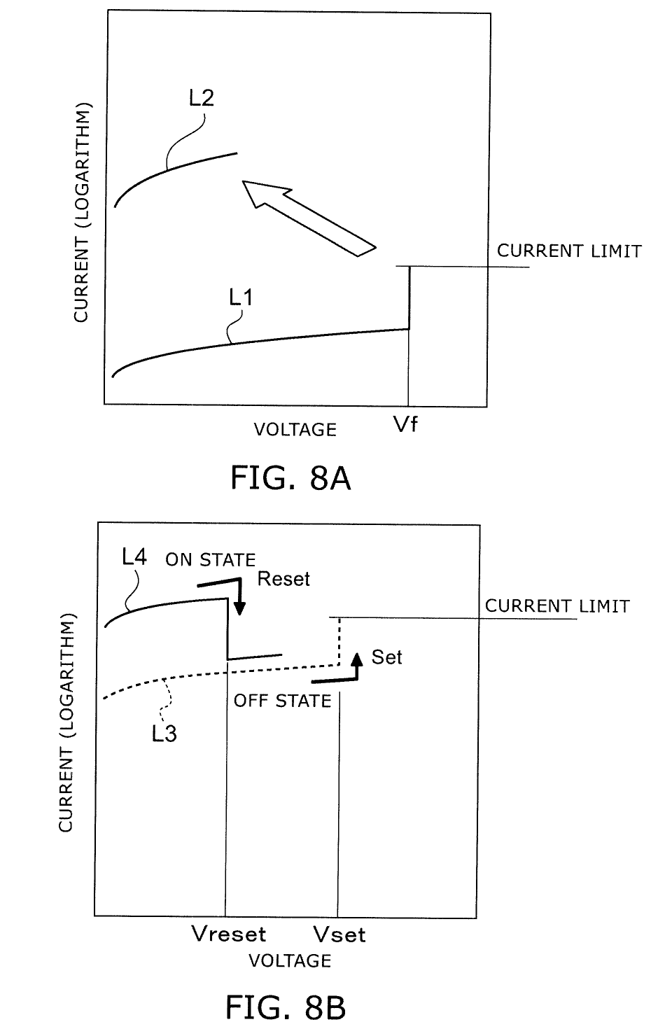

FIGS. 8A and 8B are graphs illustrating the operation of the semiconductor memory device with the voltage taken on the horizontal axis and the current taken on the vertical axis. FIG. 8A illustrates the forming operation, and FIG. 8B illustrates the set: operation and the reset operation.

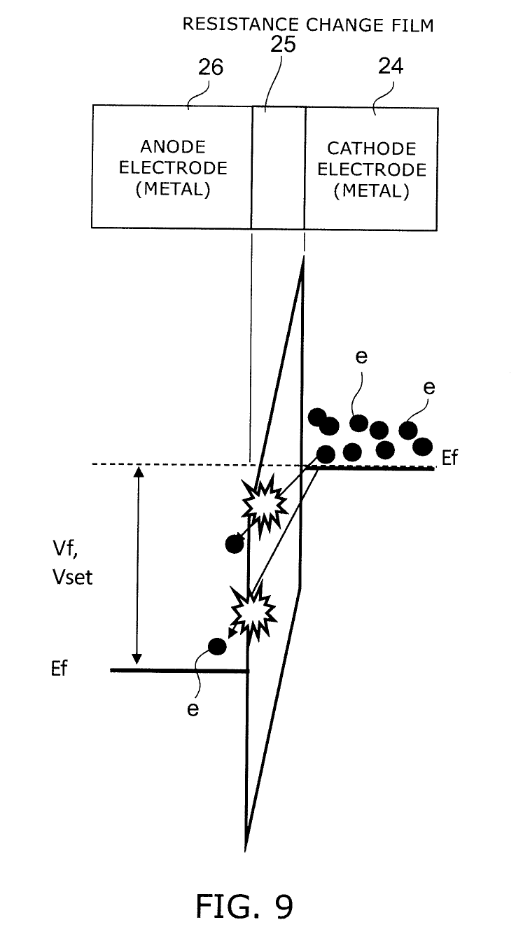

FIG. 9 is a view schematically illustrating the energy band of the resistance change element having the cathode electrode formed of a p-type semiconductor material in the forming operation and the set operation.

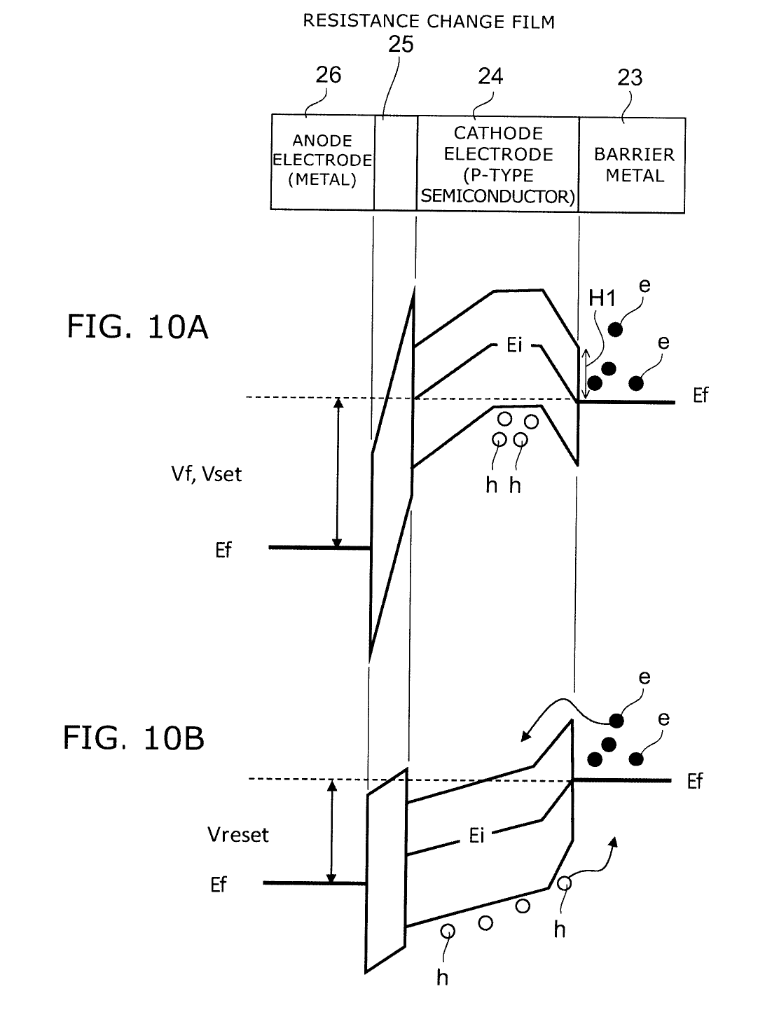

FIGS. 10A and 10B are views schematically illustrating the energy bands of the resistance change element having the cathode electrode formed of a p-type semiconductor material, and FIG. 10A illustrates the energy band in the initial state and the OFF state, and FIG. 10B illustrates the energy band of the ON state.

The resistance change film provided in the ReRam memory cell can switch between the OFF state in which the resistance value is relatively high and the ON state in which the resistance value is relatively low by the application of a prescribed voltage or current. However, generally, the resistance change film which is formed of a metal oxide or the like has the relatively high resistance value in the initial state in comparison with the resistance value in the OFF state, e.g., approximately 1×10⁹ to 1×10¹¹Ω. Then, to shift the ReRAM in the initial state as manufactured to the state in which the switching operation is possible, a voltage higher than a voltage necessary for the switching operation is necessary to be once applied to form a current path in the resistance change film to decrease the resistance of the resistance change film. This operation is called “forming operation”. Generally, when the resistance change film is formed of a metal oxide film or the like, the resistance value of the cell after the formation of the current path in the resistance change film does not substantially increase due to the decrease of the cell area; the cross-sectional area of the current path described above is considered to be several nanometers. For this reason, this current path is called “filament”.

The solid line L1 in FIG. 8A indicates the IV characteristics of the resistance change film in the initial state. As indicated by the solid line L1, the resistance value of the resistance change film is considerably high in the initial state. As the voltage applied to the resistance change film in this initial state is gradually increased, the resistance value shifts discontinuously to the low resistance state indicated by the solid line L2 at a certain voltage (Vf). The voltage Vf at this time is called a forming voltage. The state indicated by the solid line L2 is the ON state or the OFF state described above, and resistance value of the state is lower than the resistance value of the initial state indicated by the solid line L1.

At this time, when the voltage applied to the resistance change film reaches the forming voltage Vf as indicated by the solid line L1, the resistance value of the resistance change film abruptly lowers, and if this state is kept as is, a large current flows, the resistance change film will be damaged. Then, a protection mechanism is provided in the drive circuit to shut the current the instant the applied voltage reaches the forming voltage Vf.

As indicated by the broken line L3 in FIG. 8B, when a set: voltage Vset is applied to the resistance change film in the OFF state of the high resistance, the resistance change film shifts to the ON state of the low resistance. This operation is called “set operation”. In the set operation as well, the resistance value of the resistance change film abruptly lowers, and the drive circuit shuts the current the instant the voltage reaches the set voltage Vset to prevent the flow of excessive current to the resistance change film. On the other hand, as indicated by the solid line L4 in FIG. 8B, when a reset voltage Vreset is applied to the resistance change film in the ON state of the low resistance, the resistance change film shifts to the OFF state of the high resistance. This operation is called “reset operation”. In the reset operation, the resistance of the resistance change film increased, and no excessive current flows to the resistance change film. The set operation and the reset operation are repeated, whereby the ON state and the OFF state can be reversibly shifted to each other, and the resistance change element can be utilized as the memory elements.

However, in the cross-point type device such as the semiconductor memory device 1, switching elements, such as transistors or the like, are not provided for the respective memory cells, and the voltages/currents to be applied to the respective memory cells are all controlled by the drive circuit. However, the drive circuit is disposed outside of the memory cell unit 13 and is apart from the respective memory cells. Accordingly, delays take place unavoidably in transmitting signals emitted from the drive circuit to the memory cells. Resultantly, in the forming operation and the set operation described above, even when the drive circuit shuts the excessive current, the excessive current is often inputted to the resistance change film of the respective memory cells.

Especially in the resistance change element having the cathode electrode formed of a metal, as illustrated in FIG. 9, a large number of electrons e are stored in the cathode electrode in the initial state before forming and the OFF state. When the voltage applied to the resistance change film reaches the forming voltage Vf or the set voltage Vset, and the resistance of the resistance change film abruptly lowers, all the electrons e stored in the cathode electrode flow into the resistance change film although the current from the drive circuit is shut. Thus, the excessive current flows temporarily in the resistance change film, and the resistance change film is damaged. As a result, the reliability of the resistance change film may lower, and the resistance change element may not function as a memory element.

In contrast to this, as illustrated in FIG. 10A, in this embodiment, the cathode electrode 24 is formed of a p-type semiconductor material. In this case, the cathode electrode 24 is depleted, and electrons are not easily stored in the cathode electrode 24 in the initial state and the OFF state.

In the metal layer 23 contacting the cathode electrode 24, electrons e are stored, but a barrier height H1 is formed at the interface between the barrier metal layer 23 and the cathode electrode 24. Accordingly, even when the resistance value of the resistance change film 25 abruptly lowers in the forming operation or the set operation, the barrier height H1 hinders the flow of the electrons, and hence the electrons e in the barrier metal layer 24 do not simultaneously flow into the resistance change film 25. Thus, the instantaneous flow of a large current can be prevented.

Furthermore, the energy band of the cathode electrode 24 in the initial state and the OFF state is tilted by a voltage applied to the resistance change element being lower on the side of the resistance change film 25 and higher on the side of the barrier metal layer 23 for the electrons. However, at a portion contacting the barrier metal layer 23, the energy band is oppositely tilted under the influence of the Fermi level of the barrier metal layer 23. Resultantly, the cathode electrode 24 has a portion where the energy level for the holes becomes minimum, and holes h are stored in this portion and its neighborhood. A part of the electrons e which has flowed from the barrier metal layer 23 into the cathode electrode 24 recombines with the holes h stored in the cathode electrode 24 and quenched. This also suppresses the flow of all the electrons into the resistance change film 25.

On the other hand, as illustrated in FIG. 10B, after the resistance change film 25 has shifted to the ON state, the potential difference applied to the resistance change film 25 becomes small, the tilt of the energy band in the resistance change film 25 becomes small, and accompanied with this, a distribution ratio of the voltage applied to the cathode electrode 24 becomes small. This causes a current to flow in the cathode electrode 24 and the resistance change film 25, the current being mainly formed of electrons as carriers.

Next, effects of this embodiment will be described.

As described above, in this embodiment, the cathode electrode 24 contacting the resistance change film 25 is formed of a p-type semiconductor material, and hence electrons are not stored in the cathode electrode 24 in the initial state and the OFF state, and the flow of the electrons from the side of the barrier metal layer 23 can be suppressed by the barrier height H1 formed at the interface between the barrier metal layer 23 and the cathode electrode 24. Thus, the occurrence of an excessive current can be prevented in the forming operation and the set operation. Resultantly, the resistance change film is prevented from being damaged by the excessive current, and the decrease of the reliability of the resistance change film and malfunction of the resistance change element can be prevented. Thus, the variation of the memory characteristics is suppressed, and a highly reliable semiconductor memory device can be achieved.

Next, a second embodiment of this invention will be described.

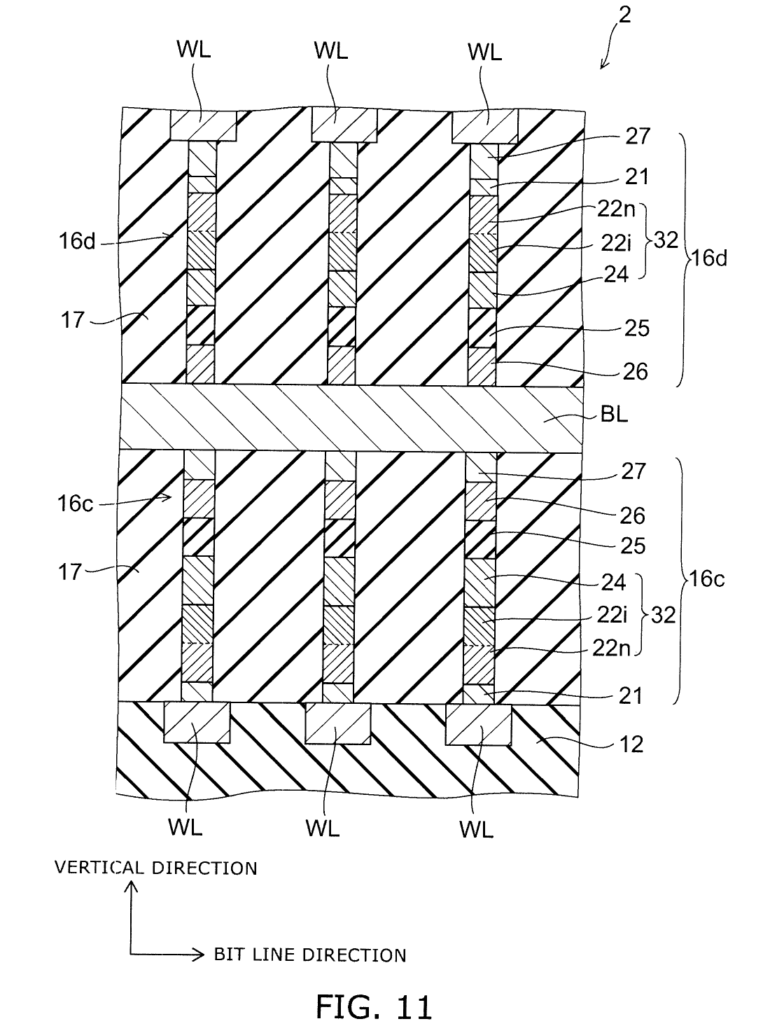

FIG. 11 is a cross-sectional view illustrating the semiconductor memory device according to this embodiment.

As illustrated in FIG. 11, the semiconductor device 2 according to this embodiment is different from the semiconductor memory device 1 according to the first embodiment described above (see FIG. 2) in the configuration of the pillars 16. That is, in the semiconductor memory device 2 as well, as illustrated in FIG. 1, the pillars 16 are provided at the respective pericenters between the word lines WL and the bit: lines BL, but the stacked structure of the respective pillars is different from that of the first embodiment.

That is, in the pillars 16c below which the word lines WL are provided and above which the bit lines BL are provided, the barrier metal layer 21, the n-type semiconductor layer 22n, the i-type (intrinsic) semiconductor layer 22i, the cathode electrodes 24, the resistance change film 25, the anode electrodes 26 and the contact metal layer 27 are stacked sequentially in the stated order from the lower side (the side of the word lines) toward above (the side of the bit lines). The cathode electrodes 24 are formed of a p-type semiconductor material, specifically p-type silicon. The n-type semiconductor layer 22n, the i-type semiconductor layer 22i and the cathode electrodes 24 (p-type semiconductor layer) form pin-type diodes 32. That is, in this embodiment, the cathode electrodes 24 act also as the p-type layer of the diodes 32. Accordingly, the barrier metal layer 23 (see FIG. 2) is omitted.

On the other hand, in the pillars 16d below which the bit lines BL are provided and above which the word lines WL are provided, the configuration of the portions of the pillars 16c except the contact metal layer 27 is inverted. That is, in the pillars 16d, the anode electrodes 26, the resistance change film 25, the cathode electrodes the i-type semiconductor layer 22i, the n-type semiconductor layer 22n, the barrier metal layer 21 and the contact metal layer 27 are stacked sequentially in the stated order from the lower side (the side of the bit lines) toward above (the side of the word lines). As in the pillars 16c, the cathode electrodes 24 (p-type semiconductor layer), the i-type semiconductor layer 22i and the n-type semiconductor layer 22n form the diodes 32, and the cathode electrodes 24 act also as the p-type layer of the diodes 32. The barrier metal layers 23 and 28 are omitted (see FIG. 2).

The material forming the barrier metal layer 21 is necessary to be a material having low electric resistivity and being able to prevent mutual diffusion between a material forming the n-type semiconductor layer 22n and a material forming the word lines WL. In addition to this, it is preferable that the material has a Fermi level (Ef) higher than the intrinsic Fermi level (Ei) of the n-type semiconductor layer 22n and more preferable that the material has a Fermi level higher than the Fermi level (Ef) of the n-type semiconductor layer 22n. The configuration of this embodiment other than the above is the same as that of the first embodiment described above.

Next, the method for manufacturing the semiconductor memory device according to this embodiment will be described.

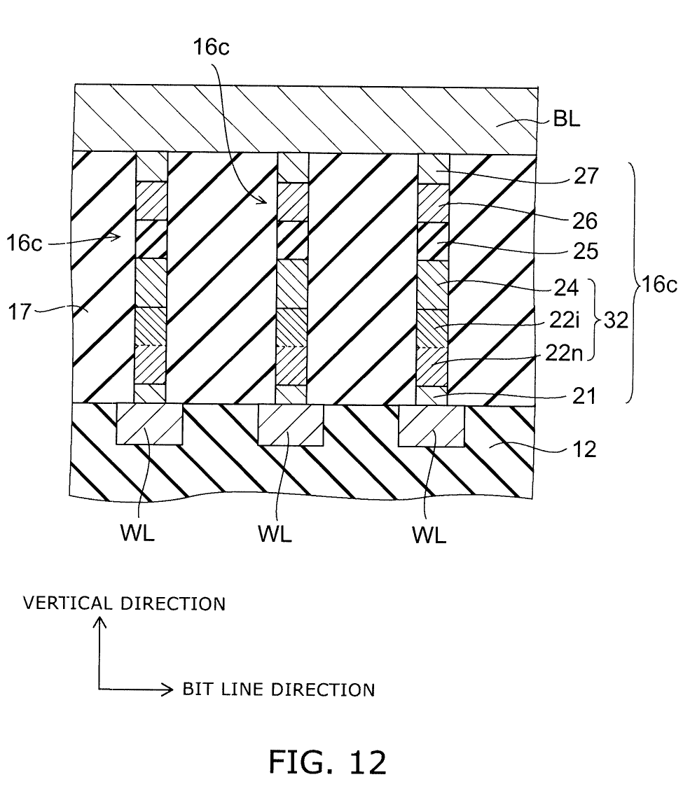

FIGS. 12 to 15 are cross-sectional views in the processes illustrating the manufacturing method of the semiconductor memory device according to this embodiment.

First, as illustrated in FIG. 1, the drive circuit is formed on the upper surface of the silicon substrate 11, and the inter-layer insulating film 12 is formed so as to bury the drive circuit. In upper layer portions of the inter-layer insulating film 12, a plurality of word lines WL are formed.

Next, as illustrated in FIG. 12, the barrier metal layer 21, the n-type semiconductor layer 22n, the i-type semiconductor layer 22i, the cathode electrodes 24, the resistance change film 25, the anode electrodes 26 and the contact metal layer 27 are stacked sequentially in the stated order on the inter-layer insulating film 12. At this time, the cathode electrodes 24 are formed of a p-type semiconductor material, e.g., silicon doped with boron. Next, the stacked body including layers from the contact metal layer 27 to the barrier metal layer 21 is processed into pillars by RIE. Thus, a plurality of the pillars 16c are formed on the word lines WL. Then, the inter-layer insulating film 17 is deposited on the inter-layer insulating film 12 to bury the pillars 16c. Then, the upper surface of the inter-layer insulating film 17 is planarized by CMP. Next, a plurality of the bit lines BL are formed in upper layer portions of the inter-layer insulating film 17 by RIE or damascening.

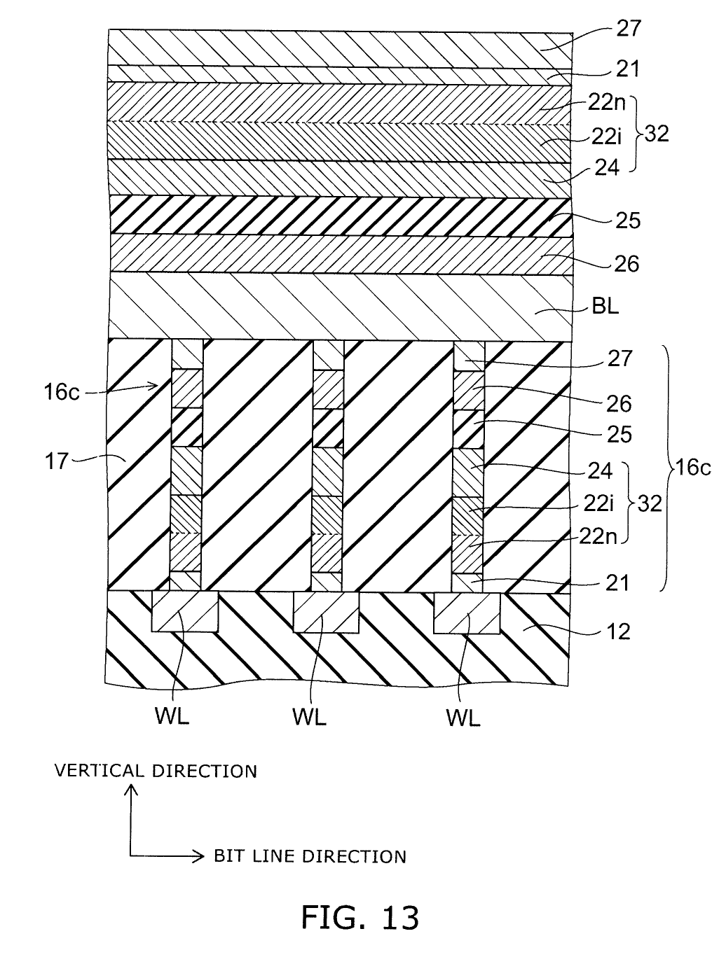

Next, as illustrated in FIG. 13, the anode electrodes 26, the resistance change film 25, the cathode electrodes 24, the i-type semiconductor layer 22i, the n-type semiconductor layer 22n, the barrier metal layer 21 and the contact metal layer 27 are stacked sequentially in the stated order on the inter-layer insulating film 17.

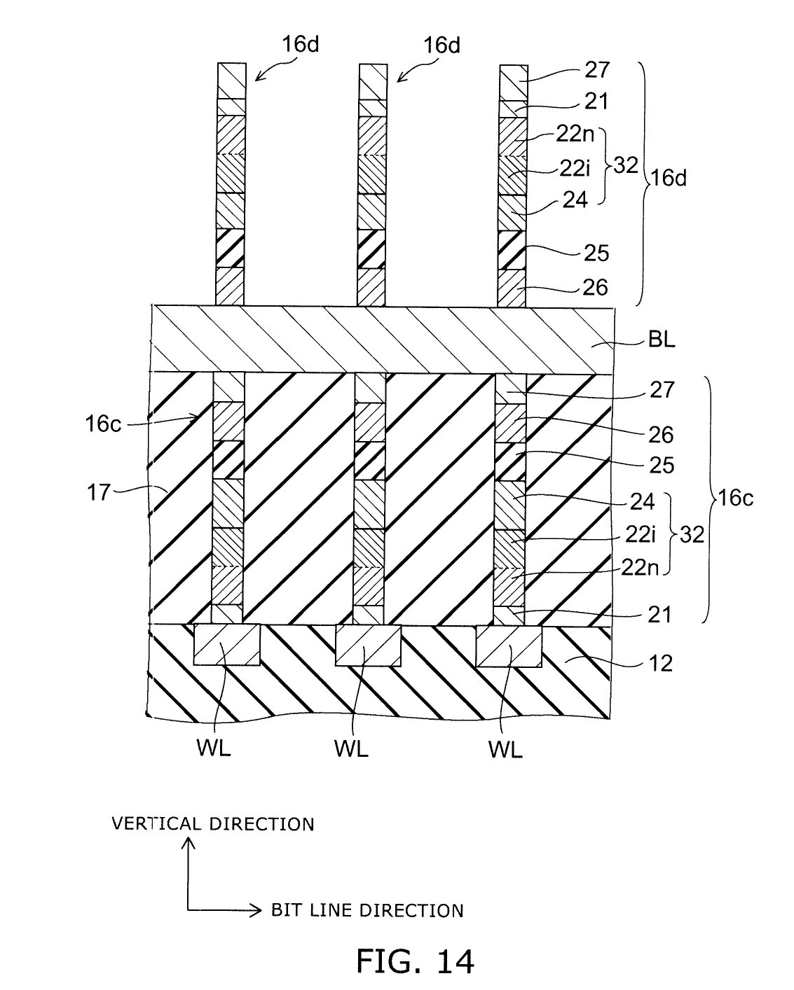

Then, as illustrated in FIG. 14, the stacked body stacked on the inter-layer insulating film 17 is processed into pillars. Thus, a plurality of the pillars 16d are formed on the bit lines BL.

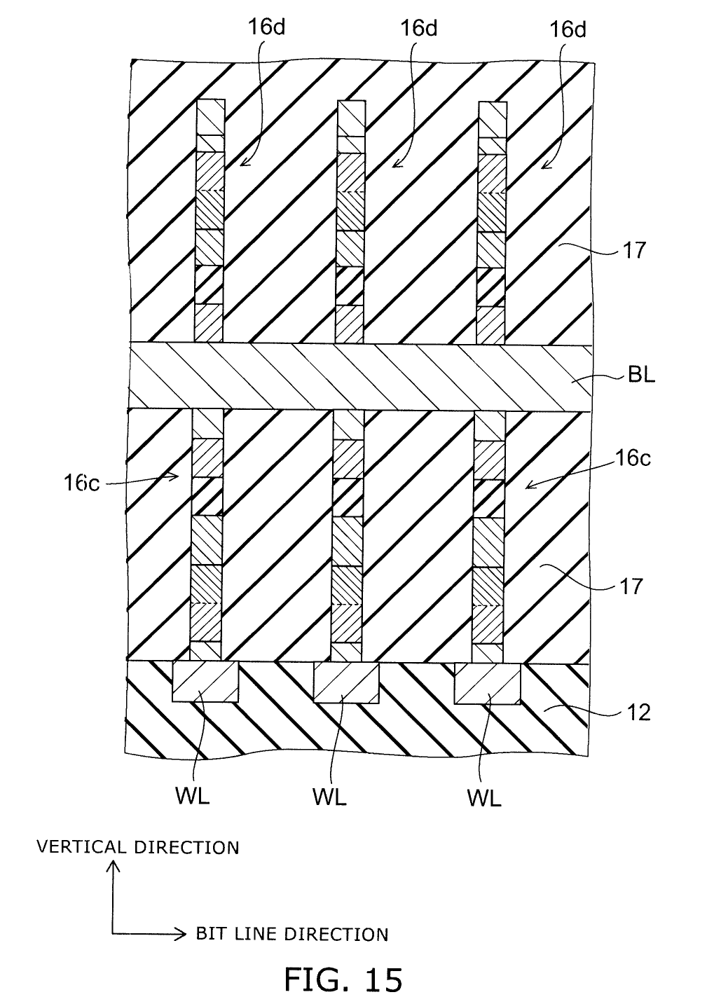

Next, as illustrated in FIG. 15, the inter-layer insulating film 17 is further deposited to bury the pillars 16d. Then, the upper surface of the inter-layer insulating film 17 is planarized by CMP.

Then, as illustrated in FIG. 11, word lines are formed in upper layer portions of the second inter-layer insulating film 17. The process described above is repeated to form the word lines WL, the pillars 16c, the bit lines BL and the pillars 16d repeatedly. Thus, the semiconductor memory device 2 is manufactured. The manufacturing method according to this embodiment other than the process described above is the same as that of the first embodiment described above.

Next, the operation of this embodiment will be described above.

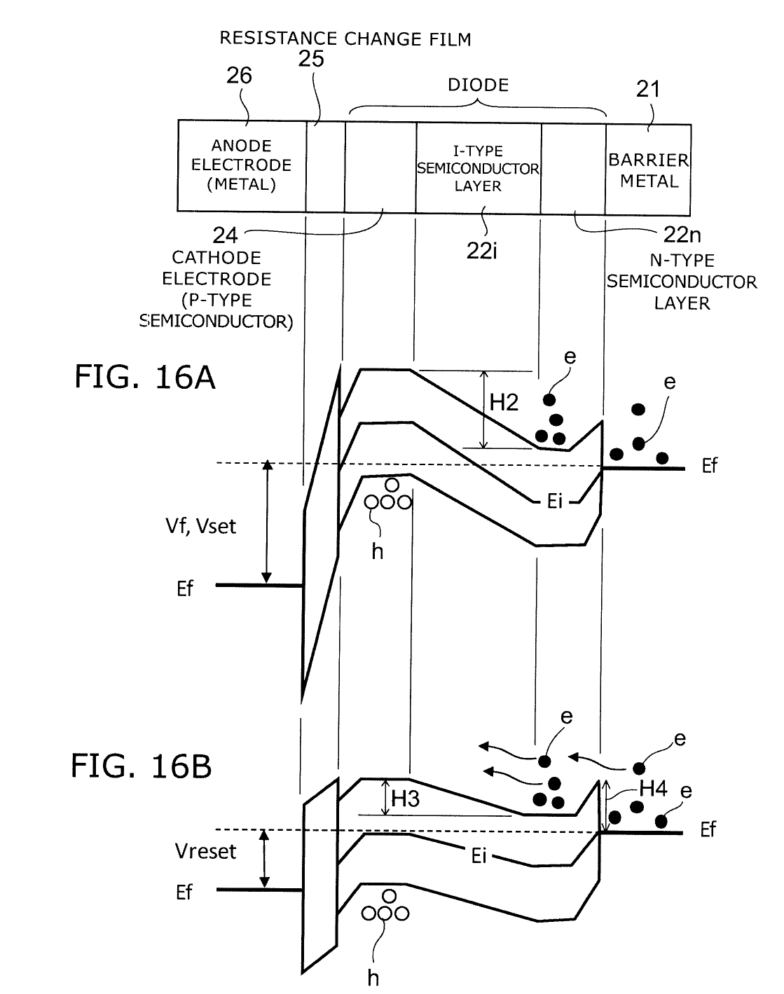

FIGS. 16A and 16B are views schematically illustrating the energy band of the pillars of this embodiment. FIG. 16A shows the initial state and the OFF state, and FIG. 16B shows the ON state.

As illustrated in FIG. 16A, in the semiconductor memory device 2 according to this embodiment, the cathode electrodes 14 of p-type silicon, the i-type semiconductor layer 22i, the n-type semiconductor layer 22n and the barrier metal layer 21 are provided sequentially in the stated order from the resistance change film 25 toward the cathode electrode side. Accordingly, in the initial state and the OFF state as well, electrons to be carriers are not substantially stored in the cathode electrodes 24 and the i-type semiconductor layer 22i. In the initial state and the OFF state, electrons are stored in the cathode electrodes 24 and the i-type semiconductor layer 22i, and these electrons are emitted in the forming operation or the set operation and do not damage the resistance change film 25.

In the n-type semiconductor layer 22n, electrons e are stored. However, the energy band of the diodes formed of the cathode electrodes 24, the i-type semiconductor layer 22i and the n-type semiconductor layer 22n is curved in an S-shape which is, for the electrons, higher at the cathode electrodes 24 and lower at the n-type semiconductor layer 22n. Accordingly, barrier height H2 formed of the cathode electrodes 24 (p-type semiconductor layer) is present between the n-type semiconductor layer 22n and the resistance change layer 25. This hinders the instantaneous flow of all the electrons e in the n-type semiconductor layer 22n into the resistance change film 25 even when the resistance value of the resistance change film abruptly lowers due to the forming operation or set operation.

As described above, the energy band of the diodes in the OFF state is S-shaped, thereby holes h are stored in the cathode electrodes 24. In the forming operation and the set operation, a part of the electrons e flowing from the n-type semiconductor layer 22n and the barrier metal layer 21 into the i-type semiconductor layer 22i is recombined with the holes h stored in the cathode electrodes 24 and quenched. This also suppresses the flow of electrons into the resistance change film 25.

On the other hand, in the reset operation for shifting the ON state to the OFF state, a certain amount of current is necessary. In this embodiment, because the cathode electrodes 24 of the resistance change elements are formed of a p-type semiconductor material, carriers must be injected into the cathode electrodes 24 in order to supply a current necessary for the reset operation to the resistance change film 25. However, the following mechanism can inject sufficient carriers.

That is, as illustrated in FIG. 16B, electrons e which are majority carriers are sufficiently present in the n-semiconductor layer 22n. When the curvature of the energy band becomes small in the ON state, the barrier height H3 for the flow of the electrons from the n-semiconductor layer 22n to the resistance change film 25 via the cathode electrodes 24 (the p-type semiconductor layer) decreases. This injects the electrons from the n-type semiconductor layer 22n into the cathode electrodes 24. That is, sufficient electrons can be injected into the cathode electrodes 24 without being influenced by the barrier height H4 of the electrons formed at the interface between the barrier metal layer 21 and the n-semiconductor layer 22n.

Resultantly, according to this embodiment, in comparison with the first embodiment described above, a large current can be easily flowed in the reset operation. In other words, a current necessary for the reset operation can be obtained under a lower rest voltage Vreset. This allows the potential difference between the set voltage Vset and the reset voltage Vreset illustrated in FIG. 8B to be large, and the voltage margin of the switch operation can be sufficiently ensured.

The material of the barrier metal layer 21 is based on a material whose Fermi level (Ef) is higher than the intrinsic Fermi level (Ei) of the n-type semiconductor layer 22n, and hence the barrier height H4 formed at the interface between the barrier metal layer 21 and the n-type semiconductor layers 22n can be decreased. This allows the current in the refer operation to be increased. The Fermi level (Ef) of the barrier metal layer 21 is made higher than the Fermi level (Ef) of the n-type semiconductor layer 22n, and hence the current can more easily flow in the reset operation. In the structure of this embodiment, although the barrier height H4 is decreased, the barrier height H2 is formed in the initial state and the OFF state before the forming, and hence even when the resistance value of the resistance change film 25 is abruptly lowered by the forming operation or the set operation, all the electrons e in the n-type semiconductor layer 22n and the barrier metal layer 21 do not instantaneously flow into the resistance change film 25.

Next, effects of this embodiment will be described.

As described above, according to this embodiment, the cathode electrodes 24 act also as the p-type layer of the diodes 32, and hence excessive currents are suppressed to decrease the damage of the resistance change film 25 in the forming operation and the set operation, and sufficient currents can be flowed in the reset operation. In comparison with the first embodiment as well, the formation of the p-type semiconductor layer 22p, and the barrier metal layers 23 and 28 can be omitted, which decreases the number of process. This decreases the manufacturing cost.

The invention has been described with reference to the embodiments, however the invention is not limited to these embodiments. Any addition, deletion, or design change of components, or any addition, omission, or condition change of processes in the above embodiments and variations suitably made by those skilled in the art are also encompassed within the scope of the invention as long as they fall within the spirit of the invention. For example, the p-type semiconductor material forming the cathode electrodes is not limited to silicon and can be other semiconductor materials. In the first embodiment described above, the rectifying devices are not limited to the pin diodes.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor memory device comprising:
a cathode electrode formed of a p-type semiconductor material;
a resistance change film being in contact with the cathode electrode; and
an anode electrode being in contact with the resistance change film.

2. The device according to claim 1, further comprising:
an intrinsic semiconductor layer being in contact with the cathode electrode;
an n-type semiconductor layer being in contact with the intrinsic semiconductor layer.

3. The device according to claim 2, further comprising
a metal layer being in contact with the n-type semiconductor layer,
a Fermi level of a metal material forming the metal layer being higher than an intrinsic Fermi level of the n-type semiconductor layer.

4. The device according to claim 1, further comprising
a rectifying element connected to the cathode electrode or the anode electrode.

5. The device according to claim 4, wherein
the rectifying element is a diode formed of silicon.

6. The device according to claim 1, wherein
the p-type semiconductor material is p-type silicon.

7. The device according to claim 1, wherein
a film thickness of the cathode electrode is 5 nm or more.

8. The device according to claim 7, wherein
the film thickness of the cathode electrode is 10 nm or more.

9. The device according to claim 1, wherein
a film thickness of the cathode electrode is 20 nm or less.

10. The device according to claim 9, wherein
the film thickness of the cathode electrode is 15 nm or less.

11. The device according to claim 1, wherein
the anode electrode is formed of a metal nitride.

12. The device according to claim 11, wherein
the anode electrode is formed of a titanium nitride.

13. The device according to claim 1, wherein
the resistance change film includes one kind of metal selected from the group consisting of nickel, titanium, zirconium, iron, vanadium, manganese, cobalt and hafnium, an alloy of two or more metals selected from the group, an oxide of the metal and the alloy or a nitride of the metal and the alloy.

14. The device according to claim 13, wherein
the resistance change film includes one or more kinds of elements selected from the group consisting of silicon, aluminum, phosphorus and arsenic by 1 to 30 percent by mass.

15. The device according to claim 13, wherein
the resistance change film is formed of the metal oxide including hafnium.

16. The device according to claim 1, wherein
a film thickness of the resistance change film is 1 to 20 nm.

17. The device according to claim 16, wherein
the film thickness of the resistance change film is 2 to 10 nm.

18. The device according to claim 1, further comprising:
a substrate;
bit line interconnection layers including a plurality of bit lines extending in a first direction; and
word line interconnection layers including a plurality of word lines extending in a second direction,
the bit line interconnection layers being alternately stacked with the word line interconnection layers on the substrate,
a pillar including the cathode electrode, the resistance change film and the anode electrode stacked being provided at each of pericenters between the bit lines and the word lines,
the anode electrode being connected to one of the bit lines, and the cathode electrode being connected to one of the word lines.
